(19) United States
(12) Patent Application Publication
(10) Pub. No.: US 2024/0047458 A1
(43) Pub. Date: Feb. 8, 2024

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Shu-Uei Jang, Hsinchu City (TW); Shih-Yao Lin, New Taipei City (TW)

(73) Assignee: Taiwan Semiconductor Manufacturing Company, Ltd., Hsinchu (TW)

(21) Appl. No.: 17/881,621

(22) Filed: Aug. 5, 2022

(51) Int. Cl. H01L 27/088; H01L 29/66; H01L 29/78; H01L 29/06; H01L 21/8234

(52) U.S. Cl. CPC H01L 27/0886; H01L 29/66795; H01L 29/7851; H01L 29/0649; H01L 21/823431; H01L 21/823481

(57) ABSTRACT

A FinFET device includes a first fin and a second fin on a substrate, a dielectric fin, a metal gate line, a gate dielectric layer, a gate isolation structure. The dielectric fin is located between the first fin and the second fin. The metal gate line is across the first fin, the dielectric fin and the second fin. The gate dielectric layer is located between the metal gate line and the dielectric fin, between the metal gate line and the first fin, and between the metal gate line and the second fin. The gate isolation structure extends through the first metal gate line and the gate dielectric layer, and landing on the dielectric fin. A top surface of the gate dielectric layer is lower than a top surface of the gate isolation structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6, 7A, 7B, 7C, 8A, 8B, 8C, 9A, 9B and 9C illustrate perspective views and cross-sectional views of intermediate stages in the formation of a Fin Field-Effect Transistors (FinFET) device, in accordance with some embodiments.

FIGS. 10A, 10B, 10C, 11A, 11B, 11C, 12A, 12B, 12C, 12D, 12E, 12F, 12G, 13A, 13B, 13C, 14A, 14B, 14C, 14D, 14E, 14F and 14G illustrate cross-sectional views of intermediate stages in the formation of gate isolation structures of a FinFET device, in accordance with some embodiments.

FIGS. 15A, 15B, 15C, 16A, 16B and 16C, illustrate cross-sectional views of intermediate stages in the formation of contacts of a FinFET device, in accordance with some embodiments.

FIGS. 17A, 17B, 17C, 17D, 17E, 17F and 17G illustrate top views and cross-sectional views of intermediate stages in the formation of an integrated circuit having gate isolation structures, in accordance with some embodiments.

FIG. 18 illustrates a method of forming a FinFET device e in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Throughout the various views and illustrative embodiments, like reference numbers are used to designate like elements. In some illustrated embodiments, the formation of Fin Field-Effect Transistors (FinFETs) is used as an example to explain the concept of the present disclosure. Other types of transistors such as planar transistors, Gate-All-Around (GAA) transistors, or the like may also adopt the embodiments of the present disclosure. Embodiments discussed herein are to provide examples to enable making or using the subject matter of this disclosure, and a person having ordinary skill in the art will readily understand modifications that may be made while remaining within contemplated scopes of different embodiments. Like reference numbers and characters in the figures below refer to like components. Although method embodiments may be discussed as being performed in a particular order, other method embodiments may be performed in any logical order. Some embodiments discussed herein are discussed in the context of FinFETs formed using a gate-last process. In other embodiments, a gate-first process may be used. Also, some embodiments contemplate aspects used in planar devices, such as planar FETs.

A semiconductor device and method of forming the same is provided in accordance with various embodiments. In particular, an isolation region is formed between neighboring gates of FinFET devices. The FinFET devices are formed in a gate-last process, where dummy gates formed of polysilicon are replaced by metal gates in intermediate steps of manufacturing. Openings are formed in the metal gates between neighboring fins using a patterning process. The patterning process is controlled such that a width of the opening is the same as or less than a width of a dielectric fin. A dielectric material is deposited into the openings to form gate isolation structures on dielectric fins. By controlling a width of the opening to be smaller than a width of the dielectric fin, the loading effect, the process window and yield can be improved.

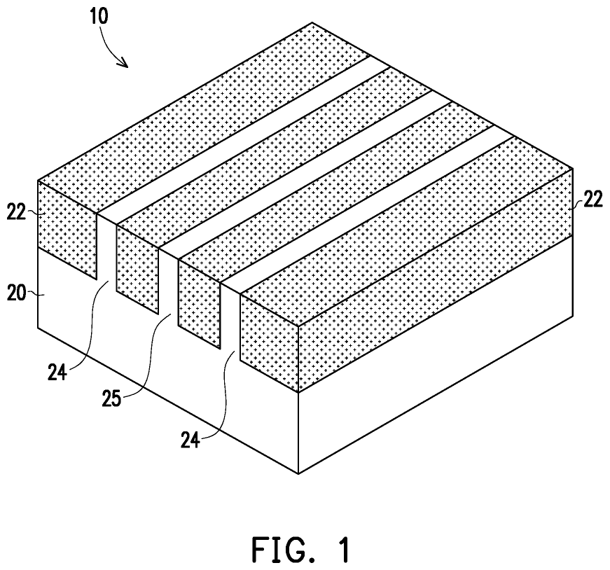

FIG. 1 illustrates a perspective view of an initial structure, in accordance with some embodiments. The initial structure includes a wafer 10, which further includes a substrate 20. The substrate 20 may be a semiconductor substrate, such as a bulk semiconductor, a semiconductor-on-insulator (SOI) substrate, or the like, which may be doped (e.g., with a p-type or an n-type dopant) or undoped. The substrate 20 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 20 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

In FIG. 1, fins 24 are shown formed in the substrate 20. The fins 24 are semiconductor strips, and may be referred to as “semiconductor strips 24” or “strips 24.” In accordance with some embodiments of the present disclosure, the fins 24 are parts of the original substrate 20, and hence the material of the fins 24 is the same as that of the substrate 20. In some embodiments, the fins 24 are formed by etching the portions of the substrate 20 to form recesses. The etching may be any acceptable etch process, such as a reactive ion etch (RIE), neutral beam etch (NBE), the like, or a combination thereof. The etch may be anisotropic. The fins 24 may be patterned by any suitable method. For example, the fins 24 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 24. In some embodiments, the mask (or other layer) may remain on the fins 24.

In some embodiments, the fins 24 may be formed by an epitaxial growth process. For example, a dielectric layer may be formed over a top surface of the substrate 20, and trenches may be etched through the dielectric layer to expose the underlying substrate 20. Homoepitaxial structures may be epitaxially grown in the trenches, and the dielectric layer may be recessed such that the homoepitaxial structures protrude from the dielectric layer to form fins. Additionally, in some embodiments, heteroepitaxial structures may be used for the fins 24. For example, the fins 24 in FIG. 1 may be recessed, and a material different from the fins 24 may be epitaxially grown over the recessed fins 24. In such embodiments, the fins 24 comprise the recessed material as well as the epitaxially grown material disposed over the recessed material. Accordingly, the fins 24 may be formed of a semiconductor material different from that of the substrate 20. In accordance with some embodiments, the fins 24 are formed of silicon; germanium; a compound semiconductor including silicon phosphide, silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

In an even further embodiment, a dielectric layer may be formed over a top surface of the substrate 20, and trenches may be etched through the dielectric layer. Heteroepitaxial structures may then be epitaxially grown in the trenches using a material different from the substrate 20, and the dielectric layer may be recessed such that the heteroepitaxial structures protrude from the dielectric layer to form the fins 24. In some embodiments where homoepitaxial or heteroepitaxial structures are epitaxially grown, the epitaxially grown materials may be in situ doped during growth, which may obviate prior and subsequent implantations although in situ and implantation doping may be used together.

As shown in FIG. 1, Shallow Trench Isolation (STI) regions 22 may be formed between the fins 24. The STI regions 22 may comprise a material such as an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other materials formed by any acceptable process may be used. An anneal process may be performed once the material is formed. Although the STI regions 22 are illustrated as a single layer, some embodiments may utilize multiple layers. For example, in some embodiments a liner (not shown) may first be formed along surfaces of the substrate 20 and the fins 24. Thereafter, a fill material, such as those discussed above, may be formed over the liner.

After forming the material of the STI regions 22, a planarization process may be performed to remove material of the STI regions 22 and expose the fins 24. The planarization process may be, for example, a chemical mechanical polish (CMP), an etch-back process, combinations thereof, or the like. The planarization process may expose the fins 24 such that top surfaces of the fins 24 and the STI regions 22 are level after the planarization process is complete. In embodiments in which a mask remains on the fins 24, the planarization process may expose the mask or remove the mask such that top surfaces of the mask or the fins 24, respectively, and the STI regions 22 are level after the planarization process is complete.

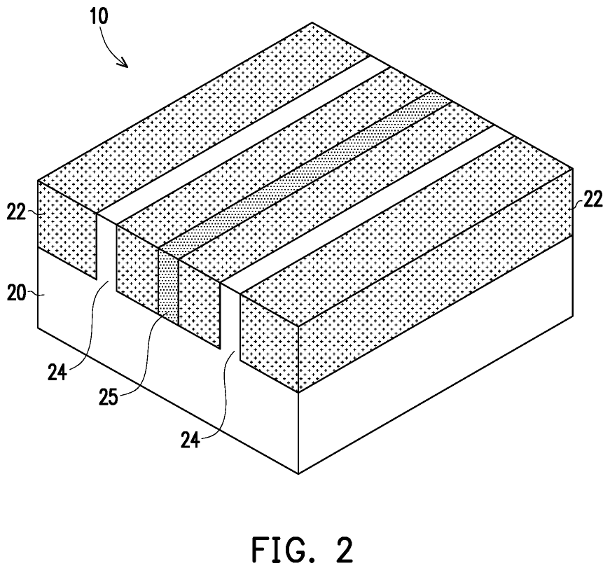

FIG. 2 illustrates the formation of a dielectric fin 25 in accordance with some embodiments, which may be formed by etching one of the fins 24 to form a recess, and then filling the recess with a dielectric material. In other embodiments, the dielectric fin 25 may be formed by etching a recess in the STI regions 22 and filling the recess with a dielectric material. In these embodiments, the bottom of the etched recess may be above a top surface of the substrate 20, level with a top surface of the substrate 20, or below a top surface of the substrate 20. The dielectric material may comprise a high-k dielectric material, a silicon oxide, a silicon nitride, the like, or combinations thereof. In some embodiments, the material of the dielectric fin 25 is selected to have a low etching selectivity relative to the material of the STI regions 22. The bottom surface of the dielectric fin 25 may be higher than, level with, or lower than, the bottom surfaces of the STI regions 22. The top surface of the dielectric fin 25 may be level with surfaces of the fins 24 or of the STI regions 22.

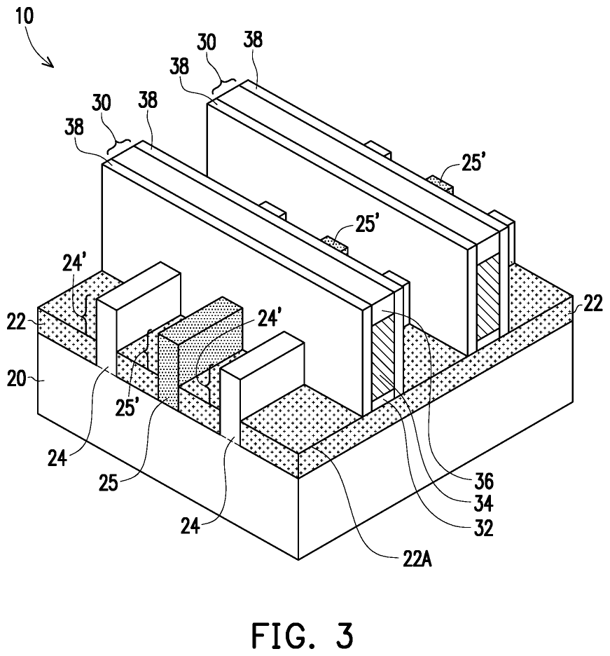

Referring to FIG. 3, the STI regions 22 are recessed. The STI regions 22 may be recessed such that top portions of the fins 24 and the dielectric fin 25 protrude higher than the top surfaces 22A of the remaining portions of STI regions 22 to form protruding fins 24′ and 25′, respectively. The top surfaces of the STI regions 22 may have a flat surface as illustrated, a convex surface, a concave surface (such as dishing), or a combination thereof. The STI regions 22 may be recessed using an acceptable etching process, such as one that is selective to the material of the STI regions 22 (e.g., etches the material of the STI regions 22 at a faster rate than the material of the fins 24 or of the dielectric fin 25). The etching may be performed, for example, using a dry etching process, such as a process in which wherein HF₃ and NH₃ are used as the etching gases. In accordance with alternative embodiments of the present disclosure, the recessing of the STI regions 22 is performed using a wet etch process. For example, an oxide removal using dilute hydrofluoric (dHF) acid may be used.

Further referring to FIG. 3, dummy gate stacks 30 are formed on the top surfaces and the sidewalls of the protruding fins 24′ and 25′. Each dummy gate stack 30 may include a dummy gate dielectric 32 and dummy gate electrode 34 formed over the dummy gate dielectric 32. Each of dummy gate stacks 30 may also include a mask layer 36 over dummy gate electrode 34. The mask layer 36 may comprise one or more layers.

The dummy gate dielectric 32 may comprise, for example, silicon oxide, silicon nitride, a combination thereof, or the like, and may be deposited or thermally grown according to acceptable techniques. The dummy gate electrode 34 may be deposited over the dummy gate dielectric 32 and then planarized, such as by a CMP. The mask layer 36 may be deposited over the dummy gate electrodes 34. The dummy gate electrode 34 may be a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals. The dummy gate electrode 34 may be deposited by physical vapor deposition (PVD), CVD, sputter deposition, or other techniques known and used in the art for depositing the selected material. The dummy gate electrode 34 may be made of other materials that have a high etching selectivity from the etching of isolation regions. The mask layer 36 may include, for example, silicon nitride, silicon oxynitride, or the like. It is noted that the dummy gate dielectric 32 is shown covering the fins 24 and the STI regions 22, but in other embodiments, the dummy gate dielectric 32 may deposited such that the dummy gate dielectric 32 does not extend on surfaces of the STI regions 22.

The mask layer 36 may be formed of silicon nitride, silicon oxide, silicon carbonitride, or multi-layers thereof. Dummy gate stacks 30 may cross over a single one or a plurality of protruding fins 24′ and 25′ and/or STI regions 22. Dummy gate stacks 30 also have lengthwise directions perpendicular to the lengthwise directions of protruding fins 24′.

Next, gate spacers 38 are formed on the sidewalls of the dummy gate stacks 30. In some embodiments, a thermal oxidation or a deposition followed by an anisotropic etch may form the gate spacers 38. In accordance with some embodiments of the present disclosure, the gate spacers 38 are formed of a dielectric material such as silicon nitride, silicon oxide, silicon carbonitride, silicon oxynitride, silicon oxycarbonitride, or the like, and may be a single-layer structure or a multi-layer structure including multiple dielectric layers. After the formation of the gate spacers 38, implants for lightly doped source/drain (LDD) regions (not explicitly illustrated) may be performed. In some embodiments, one or more layers of the gate spacers 38 are formed after implantation of the LDD regions.

In above-illustrated embodiments, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

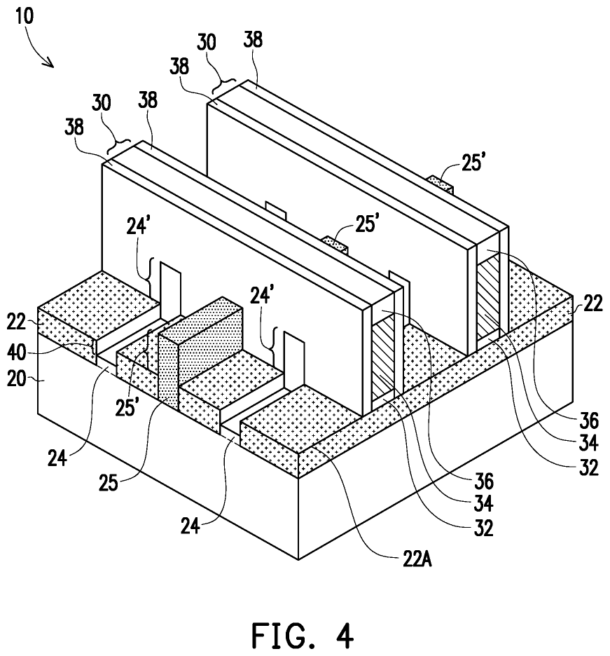

In FIG. 4, an etching step (referred to as source/drain recessing hereinafter) may be performed to etch the portions of the protruding fins 24′ that are not covered by the dummy gate stack 30 and the gate spacers 38, in accordance with some embodiments of the present disclosure. The recessing may be anisotropic etching process that does not etch the portions of the protruding fins 24′ directly underlying the dummy gate stacks 30 and the gate spacers 38. The top surfaces of the recessed fins 24 may be lower than the top surfaces 22A of the STI regions 22. The spaces left by the etched portions of the protruding fins 24′ are referred to as recesses 40. In the etching process, the dielectric fin 25′ is not etched. For example, the protruding fins 24′ may be etched using a selective etch such as NF₃ and NH₃, HF and NH₃, or the like.

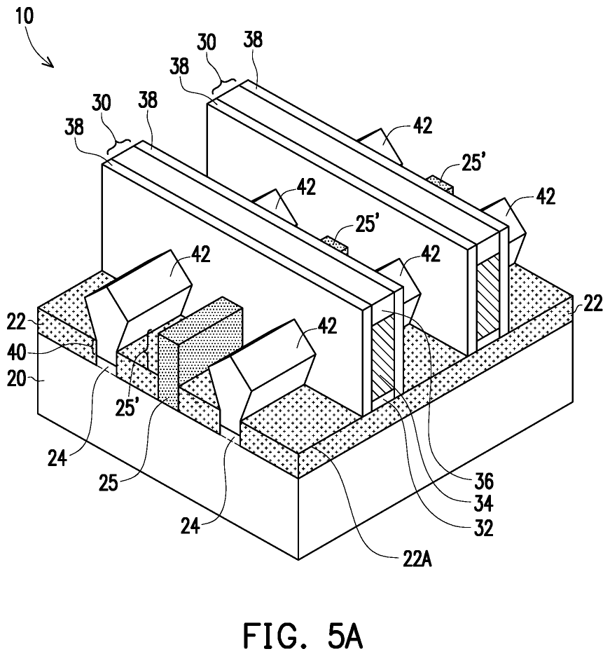

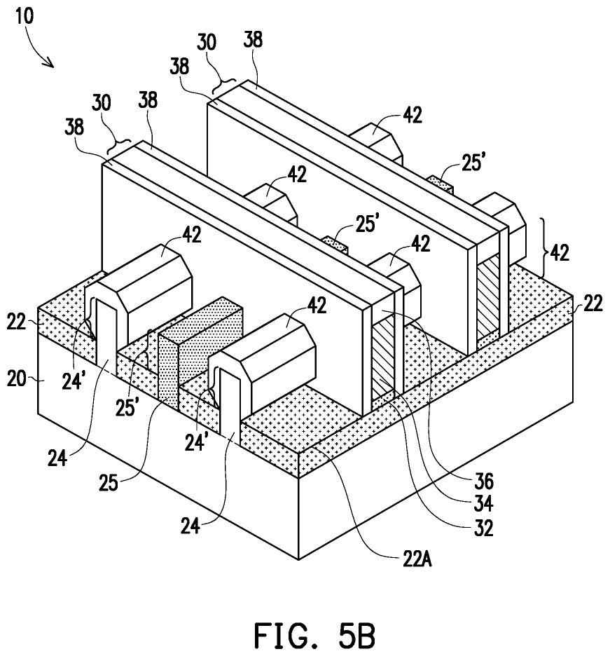

Turning to FIGS. 5A and 5B, epitaxial source/drain regions 42 are formed, in accordance with some embodiments. The epitaxial source/drain regions 42 may be formed, for example, by selectively growing semiconductor material(s) from the recesses 40, resulting in the structure shown in FIG. 5A. In accordance with some embodiments, the epitaxial source/drain regions 42 include silicon germanium, silicon, silicon carbon, germanium, the like, or combinations thereof. Depending on whether the resulting FinFET is a p-type FinFET or an n-type FinFET, a p-type or an n-type impurity may be in-situ doped during the epitaxial growth process. For example, when the resulting FinFET is a p-type FinFET, silicon germanium, germanium, germanium tin, boron-doped silicon germanium (SiGeB), boron-doped germanium, the like, or combinations thereof may be grown. When the resulting FinFET is an n-type FinFET, silicon phosphide (SiP), silicon carbide (SiC), phosphorous-doped silicon carbide (SiCP), or the like, may be grown. In accordance with alternative embodiments of the present disclosure, epitaxial source/drain regions 42 are formed of a III-V compound semiconductor such as GaAs, InP, GaN, InGaAs, InAlAs, GaSb, AlSb, AlAs, AlP, GaP, combinations thereof, or multi-layers thereof. The epitaxial source/drain regions 42 may also have surfaces raised from respective surfaces of the fins 24 and may have facets.

FIG. 5B illustrates the formation of epitaxial source/drain regions 42 in accordance with alternative embodiments of the present disclosure, in which the protruding fins 24′ as shown in FIG. 4 are not recessed, and the epitaxial source/drain regions 42 are grown on the protruding fins 24′. The material of the epitaxial source/drain regions 42 of FIG. 5B may be similar to that of the epitaxial source/drain regions 42 as shown in FIG. 5A, depending on whether the resulting FinFET is a p-type or an n-type FinFET. In some cases, the epitaxial source/drain regions 42 may be considered to also include the protruding fins 24′. An implantation may (or may not) be performed to implant the epitaxial source/drain regions 42 with an n-type impurity or a p-type impurity. Subsequent Figures illustrate structures formed from the structure shown in FIG. 5B, but the embodiments and techniques described herein may be used with the structure shown in FIG. 5A or other structures, embodiments, or devices.

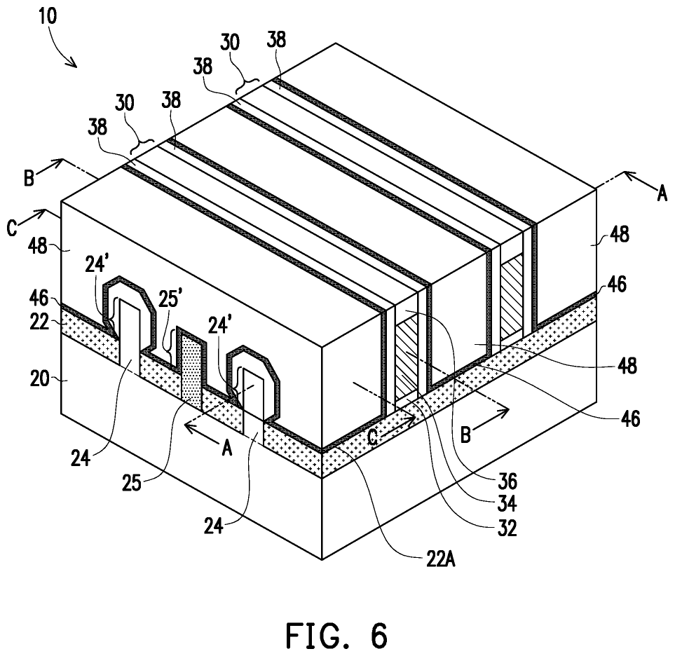

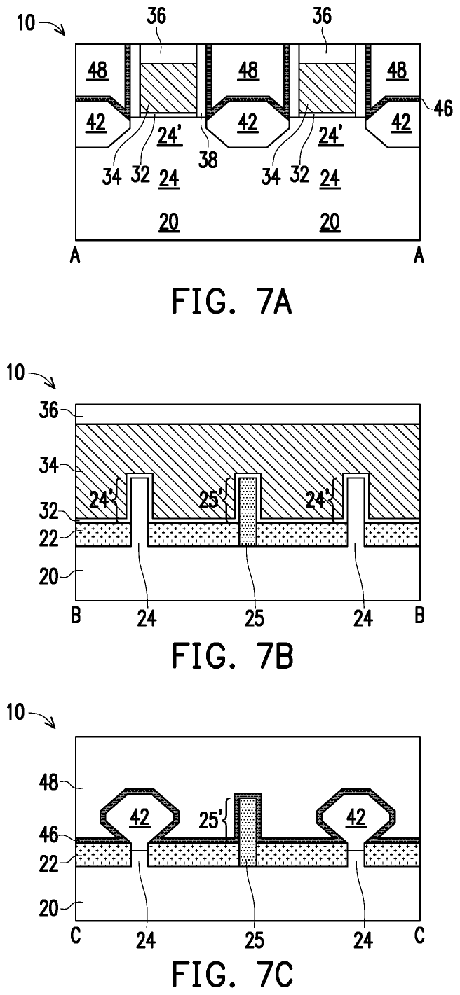

FIG. 6 illustrates the formation of a first interlayer dielectric (ILD) 48 in accordance with some embodiments of the present disclosure. FIGS. 7A, 7B, and 7C illustrate cross-sectional views of the structure shown in FIG. 6, in accordance with some embodiments. FIG. 7A is illustrated along cross-section A-A, FIG. 7B is illustrated along cross-section B-B, and FIG. 7C is illustrated along cross-section C-C.

In FIG. 6 and FIG. 7A to FIG. 7C, the first interlayer dielectric (ILD) 48 is deposited over the structure illustrated in FIG. 5B. The first ILD 48 may be formed of a dielectric material, and may be deposited by any suitable method, such as CVD, plasma-enhanced CVD (PECVD), or flowable CVD (FCVD). Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 46 is disposed between the first ILD 48 and the epitaxial source/drain regions 42, the mask layer 36, and the gate spacers 38. The CESL 46 may comprise a dielectric material, such as, silicon nitride, silicon oxide, silicon oxynitride, silicon carbonitride, or the like, having a different etch rate than the material of the overlying first ILD 48. A planarization process such as a CMP process or a mechanical grinding process may be performed to level the top surfaces of ILD 48, dummy gate stacks 30, and gate spacers 38 with each other, as shown in FIG. 6 and FIG. 7A.

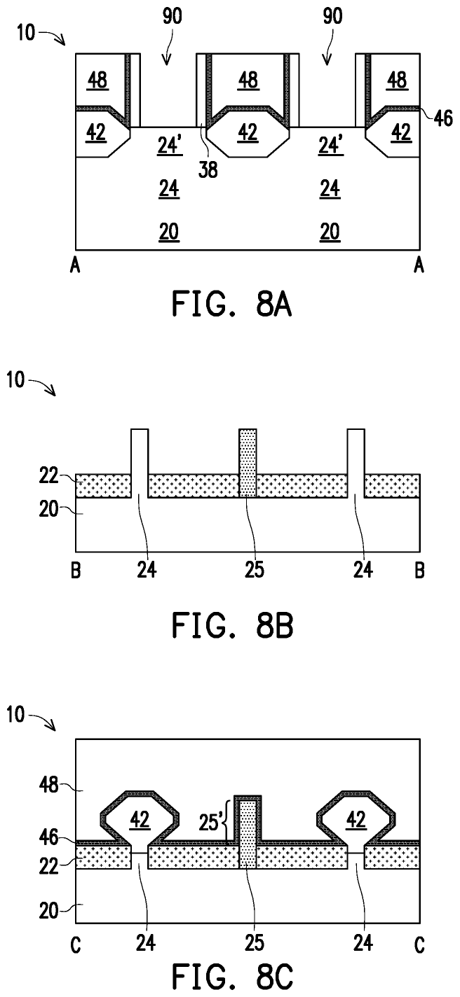

In FIGS. 8A to 8C, the dummy gate dielectric 32, and the dummy gate electrode 34 are removed, in accordance with some embodiments. In some embodiments, the dummy gate dielectric 32, and the dummy gate electrode 34 are removed using an anisotropic dry etch process. For example, the etching process may include a dry etch process using reaction gas(es) that selectively etches the dummy gate dielectric 32, and the dummy gate electrode 34 without etching the first ILD 48, or the gate spacers 38. In some embodiments, a wet etch process or an oxide removal process may be used. In some embodiments, the dummy gate dielectric 32 is removed from recesses 90 in a first region of a die (e.g., a core logic region) and remains in recesses 90 in a second region of the die (e.g., an input/output region). The removal of the dummy gate dielectric 32 and the dummy gate electrode 34 forms a recess 90 that exposes a channel region of a respective fin 24. During the removal, the dummy gate dielectric 32 may be used as an etch stop layer when the dummy gate electrodes 34 are etched. The dummy gate dielectric 32 may then optionally be removed after the removal of the dummy gate electrodes 34.

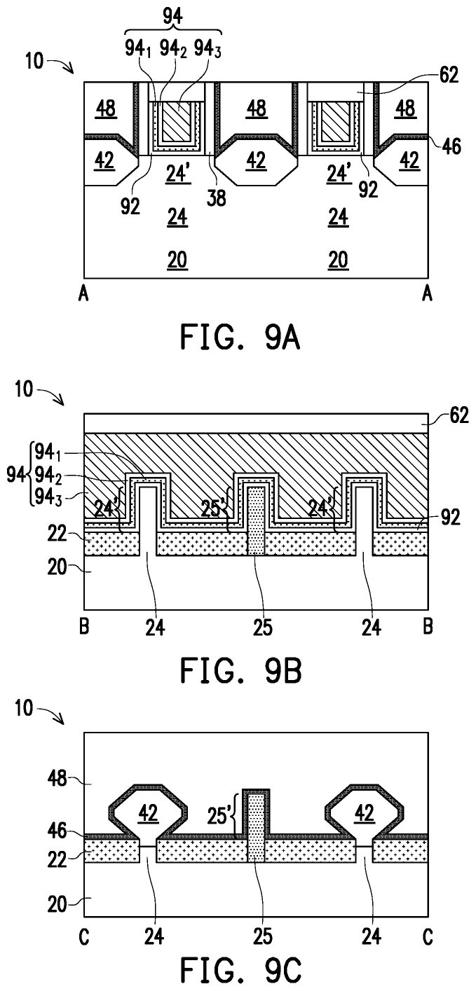

In FIGS. 9A to 9C, gate dielectric layers 92 and gate electrodes 94 are formed for replacement gates. The gate dielectric layers 92 are deposited conformally in the recesses 90, such as on the top surfaces and the sidewalls of the fins 24 and on sidewalls of the gate spacers 38. The gate dielectric layers 92 may also be formed on the top surface of the first ILD 48. In accordance with some embodiments, the gate dielectric layers 92 comprise silicon oxide, silicon nitride, or multilayers thereof. In some embodiments, the gate dielectric layers 92 include a high-k dielectric material, and in these embodiments, the gate dielectric layers 92 may have a k value greater than about 7.0, and may include a metal oxide or a silicate of hafnium, aluminum, zirconium, lanthanum, manganese, barium, titanium, lead, and combinations thereof. The formation methods of the gate dielectric layers 92 may include Molecular-Beam Deposition (MBD), ALD, PECVD, and the like. In embodiments where portions of the dummy gate dielectric 32 remains in the recesses 90, the gate dielectric layers 92 include a material of the dummy gate dielectric 32 (e.g., SiO₂). A thickness of the gate dielectric layers 92 is in a range between 20 nm and 1000 nm.

The gate electrodes 94 are deposited over the gate dielectric layers 92, respectively, and fill the remaining portions of the recesses 90. The gate electrodes 94 may include a metal-containing material such as titanium nitride, titanium oxide, tantalum nitride, tantalum carbide, cobalt, ruthenium, aluminum, tungsten, combinations thereof, or multi-layers thereof. The gate electrode 94 may be a single layer or multiple layers. In some embodiments, the gate electrode 94 may include any number of liner layers 94₁, any number of work function tuning layers 94₂, and a fill material 94₃ as illustrated by FIGS. 9A and 9B. After the filling of the recesses 90, a planarization process, such as a CMP, may be performed to remove the excess portions of the gate dielectric layers 92 and the material of the gate electrodes 94, which excess portions are over the top surface of the ILD 48. The remaining portions of material of the gate electrodes 94 thus form metal gate lines of the resulting FinFETs.

The formation of the gate dielectric layers 92 in different regions of the wafer 10 may occur simultaneously such that the gate dielectric layers 92 in each region are formed from the same materials, and the formation of the gate electrodes 94 may occur simultaneously such that the gate electrodes 94 in each region are formed from the same materials. In some embodiments, the gate dielectric layers 92 in each region may be formed by distinct processes, such that the gate dielectric layers 92 may be different materials, and/or the gate electrodes 94 in each region may be formed by distinct processes, such that the gate electrodes 94 may be different materials. Various masking steps may be used to mask and expose appropriate regions when using distinct processes.

In FIGS. 9A to 9C, hard masks 62 are formed over the gate dielectric layers 92 and the gate electrodes 94, in accordance with some embodiments. In some embodiments, the hard masks 62 are formed of silicon nitride, silicon oxynitride, silicon oxycarbide, silicon oxycarbonitride, the like, or combinations thereof. The formation of the hard masks 62 may include recessing the gate dielectric layers 92 and corresponding overlying gate electrodes 94 using one or more etching processes to form recesses, so that a recess is formed directly over the gate dielectric layers 92 and the gate electrodes 94 and between opposing portions of gate spacers 38. Then, a dielectric material is filled into the recesses, and planarization process is performed to remove the excess portions of the dielectric material. The remaining portions of the dielectric material are the hard masks 62.

The hard masks 62, the gate electrodes 94 and the gate dielectric layers 92 thus form replacement gates of the resulting FinFETs. Thus, the hard masks 62, the gate electrodes 94 and the gate dielectric layers 92 may be collectively referred to as a “replacement gate stack” or a “gate stack.” The replacement gate stacks may extend along sidewalls of a channel region of the fins 24.

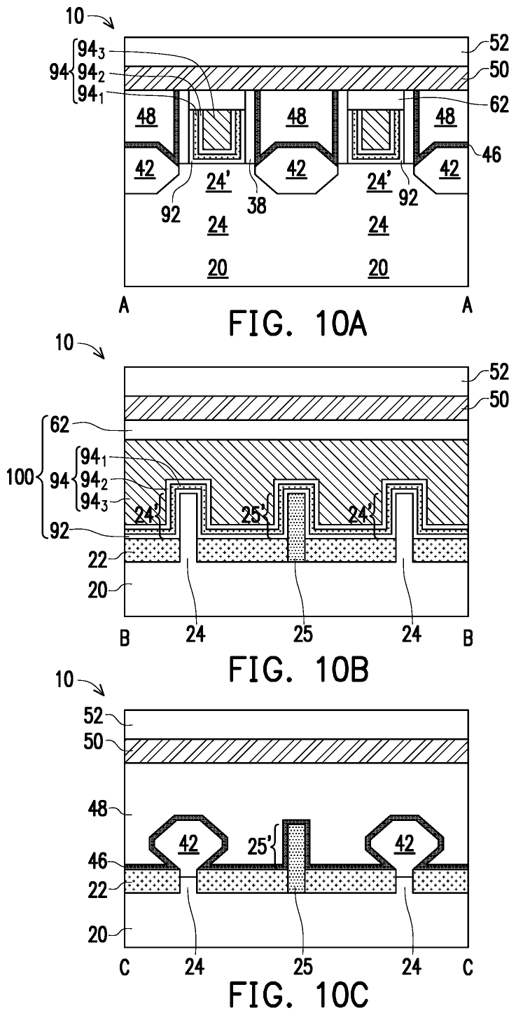

FIGS. 10A through 16C illustrate a gate isolation process (FIGS. 10A-14C) followed by a process for forming contacts (FIGS. 15A-16C).

In FIGS. 10A to 10C, a mask layer 50, such as a hard mask, is deposited over the structure illustrated in FIGS. 9A to 9C, and a photoresist structure 52 is formed over the mask layer 50, in accordance with some embodiments. The mask layer 50 may comprise silicon nitride, silicon oxynitride, silicon carbonitride, silicon oxycarbonitride, silicon oxide, the like, or a combination thereof. The mask layer 50 may be formed by CVD, PVD, ALD, a spin-on-dielectric process, the like, or a combination thereof. In some embodiments, the mask layer 50 is formed having a thickness that is between about 20 nm and about 120 nm. In some embodiments, the photoresist structure 52 is formed using a spin-on technique or the like, and may be formed having a thickness that is between about 5 nm and about 20 nm. These are examples, and other thicknesses or techniques are possible.

In some embodiments, the photoresist structure 52 is a tri-layer photoresist structure. In these embodiments, the tri-layer photoresist structure 52 includes a top photoresist layer, a middle layer, and a bottom layer (not individually labeled in FIGS. 10A to 10C). As the limits of photolithography processes are reached by advanced semiconductor manufacturing processes, the need for thinner top photoresist layers has arisen to achieve smaller process windows. However, thin top photoresist layers may not be sufficiently robust to support the etching of target layers (e.g., the mask layer 50). The tri-layer photoresist structure 52 may provide a relatively thin top photoresist layer. The middle layer may include anti-reflective materials (e.g., a backside anti-reflective coating (BARC) layer) to aid the exposure and focus of the top photoresist layer's processing. By having the middle layer, the thin top photoresist layer is only used to pattern the middle layer. The bottom layer may include a hard mask material such as a carbon-containing material that is easily removed by O₂, a N₂/H₂ plasma, or the like. The middle layer is used to pattern the bottom layer. In some embodiments, the middle layer has a high etch selectivity to the bottom layer, and in some embodiments, the bottom layer is more than ten times thicker than the middle layer. Thus, the tri-layer photoresist structure 52 allows for the robust patterning of underlying layers (e.g., the mask layer 50) while still providing a relatively thin top photoresist layer.

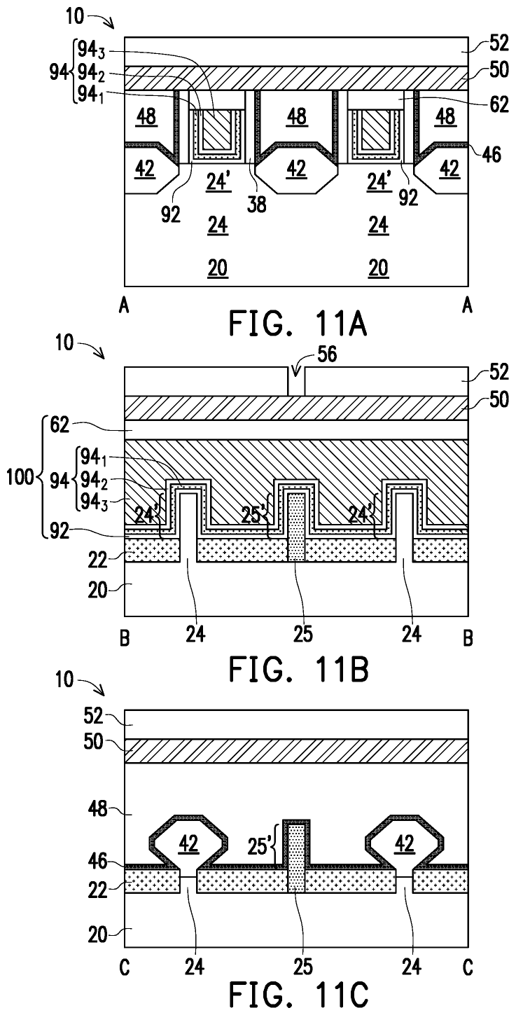

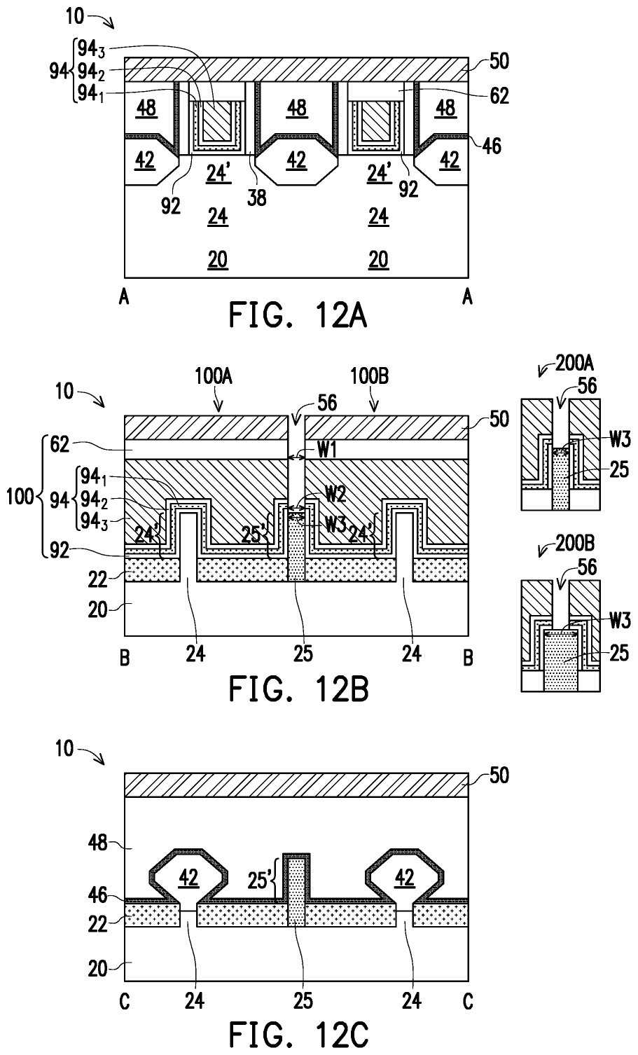

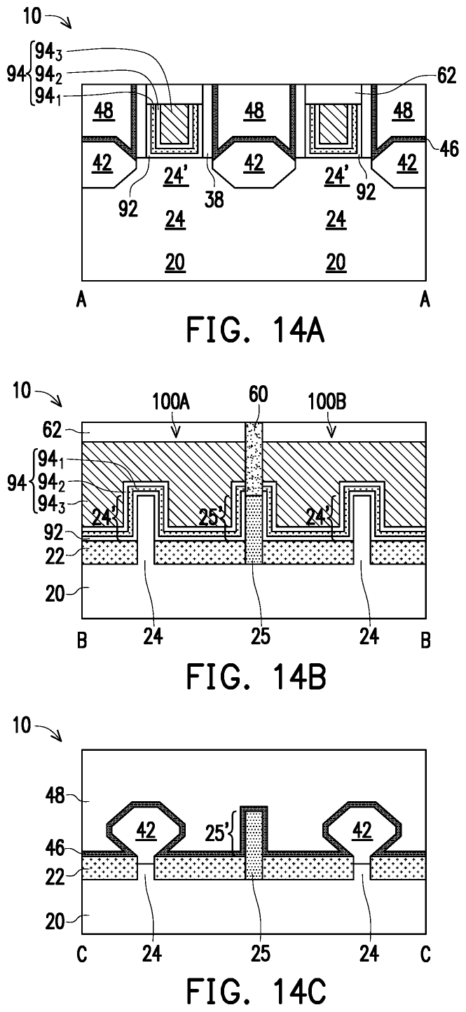

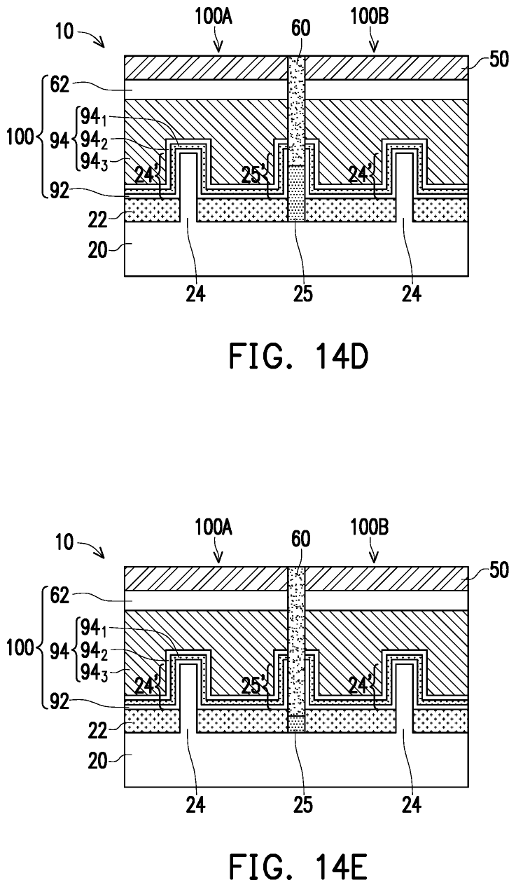

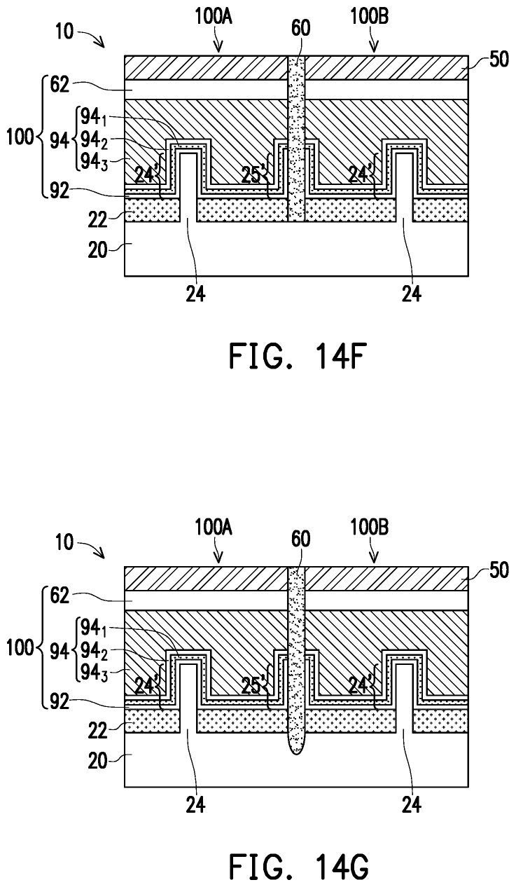

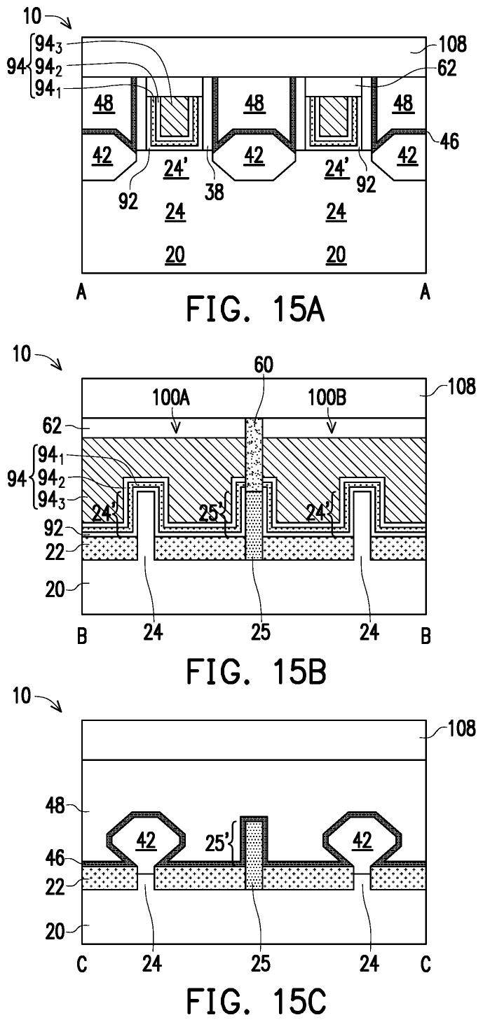

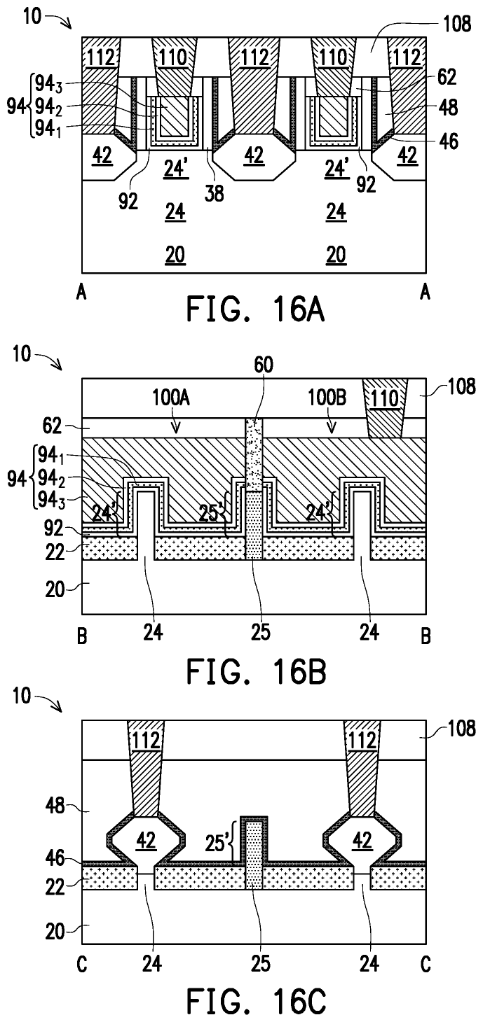

In FIGS. 11A to 11C, a cutting process is performed by patterning the photoresist structure 52 to form one or more gate isolation openings 56 that expose the mask layer 50, in accordance with some embodiments. The gate isolation openings 56 are used to subsequently form gate isolation structures 60 (see FIG. 14B). As such, the gate isolation openings 56 may be located over one or more gate electrodes 94 (see FIG. 11A) and/or over one or more dielectric dielectric fins 25 (see FIGS. 11B and 11C).

The photoresist structure 52 may be patterned to form gate isolation openings 56 using acceptable photolithography techniques. After the photoresist structure 52 is patterned, a trimming process may be performed on the patterned photoresist structure 52. In an embodiment, the trimming process is an anisotropic plasma etch process with process gases including O₂, CO₂, N₂/H₂, H₂, the like, a combination thereof, or any other gases suitable for trimming photoresist.

In embodiments in which the photoresist structure 52 is a tri-layer photoresist structure, the top photoresist layer of the tri-layer photoresist 52 may be patterned using any suitable photolithography technique. For example, a photomask (not shown) may be disposed over the top photoresist layer, which may then be exposed to radiation, for example, from a laser beam. Exposure of the top photoresist layer may be performed using an immersion lithography system to increase resolution and decrease the minimum achievable pitch. A bake or cure operation may be performed to harden the top photoresist layer, and a developer may be used to remove either the exposed or unexposed portions of the top photoresist layer depending on whether a positive or negative resist is used. After the patterning of the top photoresist layer of the tri-layer photoresist structure 52, a trimming process may be performed on the top photoresist layer of the tri-layer photoresist structure 52. After the trimming process, the middle and bottom layers may be patterned leaving the patterned tri-layer photoresist structure 52 with gate isolation openings 56, as illustrated in FIGS. 11A to 11C.

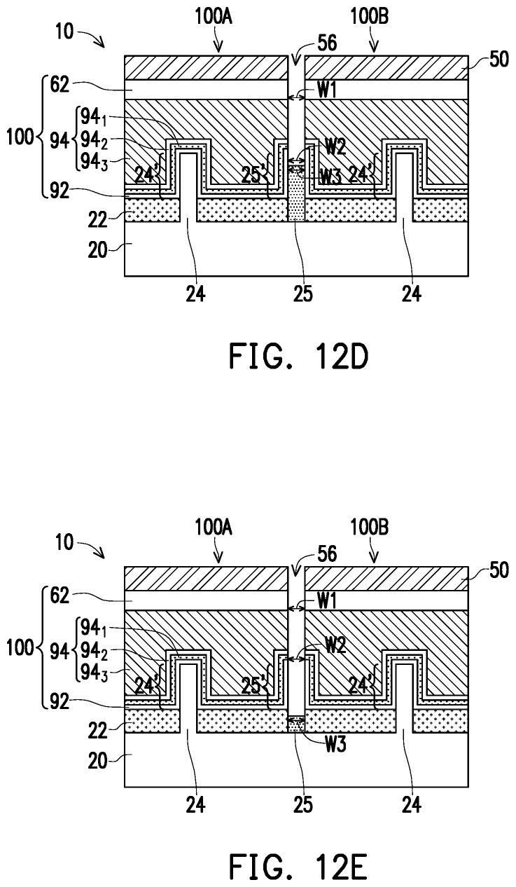

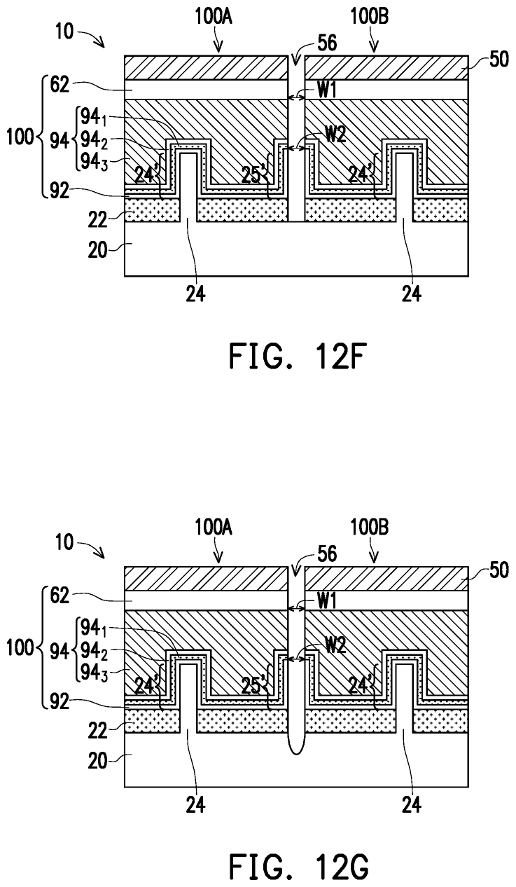

FIGS. 12A to 12C illustrate using the patterned photoresist structure 52 as an etching mask to extend the gate isolation opening 56 through the mask layer 50 and into the gate stack 100, in accordance with some embodiments. As shown in FIGS. 12A to 12 C, the gate isolation opening 56 may be extended through the gate electrode 94 to the dielectric fin 25. The dielectric fin 25 may be exposed by the gate isolation opening 56, or the dielectric fin 25 may remain covered by the gate dielectric layer 92. In this manner, the gate isolation opening 56 separates the gate stack 30 of the structure shown in FIGS. 12A-12C into two separate and electrically isolated gate stacks 100A and 100B. The formation of the gate isolation openings 56 to form separate gate stacks 100A and 100B may thus be considered a “gate-cut” process. It should be understood that a single gate stack 100 may be separated into more than two gate stacks 100A and 100B by the formation of additional gate isolation openings 56, which may be formed simultaneously.

The gate isolation opening 56 may be extended through the mask layer 50 and into the gate stack 100 using one or more suitable etching processes, such as an isotropic dry etching processes, described in greater detail below. In some embodiments, the gate isolation openings 56 have substantially vertical sidewalls as shown in FIG. 12B or have a substantially uniform width. In other some embodiments, the gate isolation openings 56 have angled sidewalls or have a tapered width (not shown). For example, a gate isolation opening 56 may have an upper width W1 that is larger than or equal to its lower width W2. In some embodiments, the lower width W2 of a gate isolation opening 56 may be equal to a width W3 of a corresponding dielectric fin 25 as shown in an enlarged view 200A. In alternative embodiments, the lower width W2 of a gate isolation opening 56 may be less than a width W3 of a corresponding dielectric fin 25 as shown in an enlarged view 200B.

FIGS. 12D to 12G illustrate gate isolation openings 56 with various depths in accordance with alternative embodiments. The gate isolation openings 56 shown in FIGS. 12D to 12G are shown in a cross-sectional view similar to FIG. 12B.

FIGS. 12D and 12E illustrates embodiments in which the bottom of the gate isolation opening 56 extends below the top of the dielectric fin 25 and a dielectric fin 25 may be present under the gate isolation opening 56.

As shown in FIG. 12D, the etching process may remove portions of the dielectric fin 25 such that a top surface of the remaining dielectric fin 25 is lower than a top surface of the fin 24. The gate isolation opening 56 may also have a bottom width W2 that is less than or equal to the width W3 of the dielectric fin 25.

As shown in FIG. 12E, the gate isolation opening 56 may extend to the STI regions 22 or into the STI regions 22, such that a top surface of the remaining dielectric fin 25 is lower than a top surface of the STI regions 22. The gate isolation opening 56 may also have a bottom width W2 that is less than or equal to the width W3 of the dielectric fin 25.

FIG. 12F illustrates an embodiment in which the gate isolation opening 56 extends into the STI regions 22. In some embodiments, the gate isolation opening 56 may extend fully through the STI regions 22 to expose the substrate 20. FIG. 12F also shows an embodiment in which no dielectric fin 25 is present.

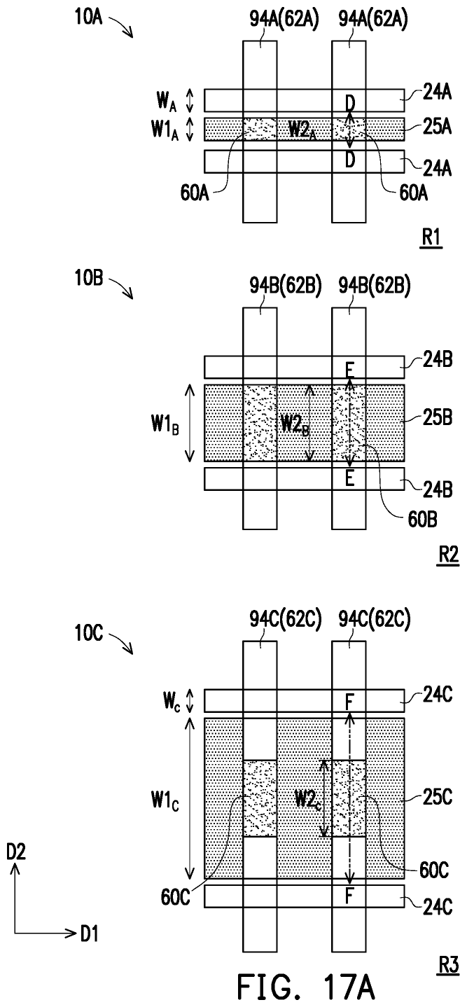

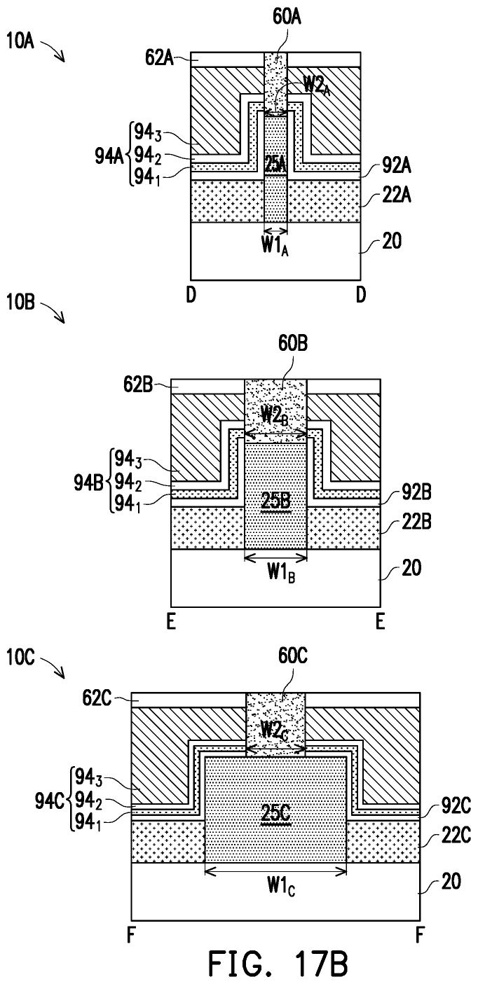

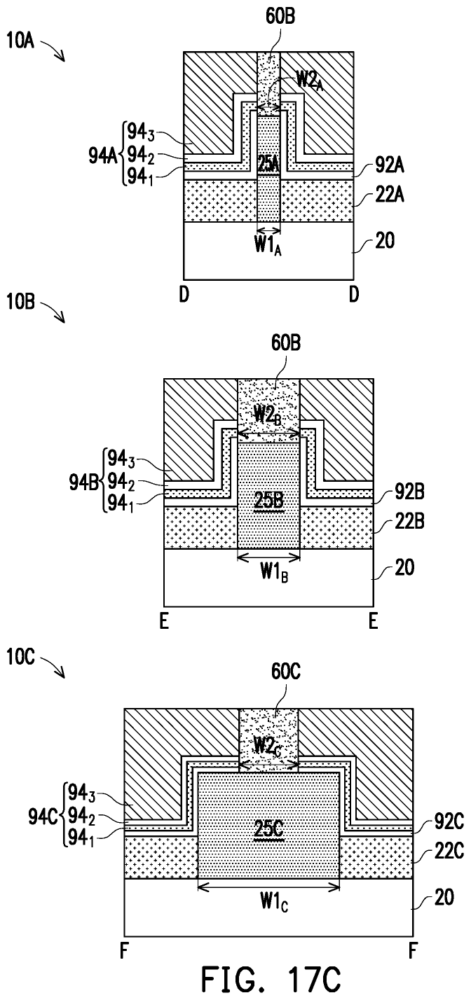

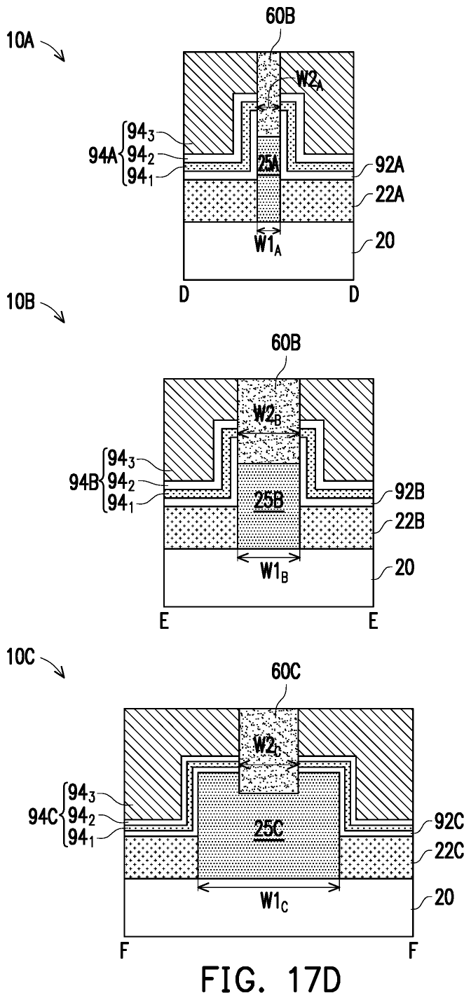

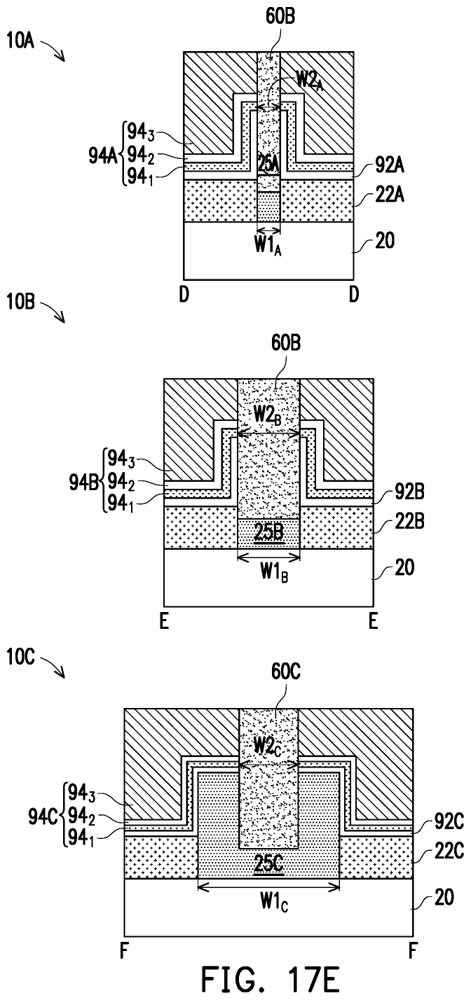

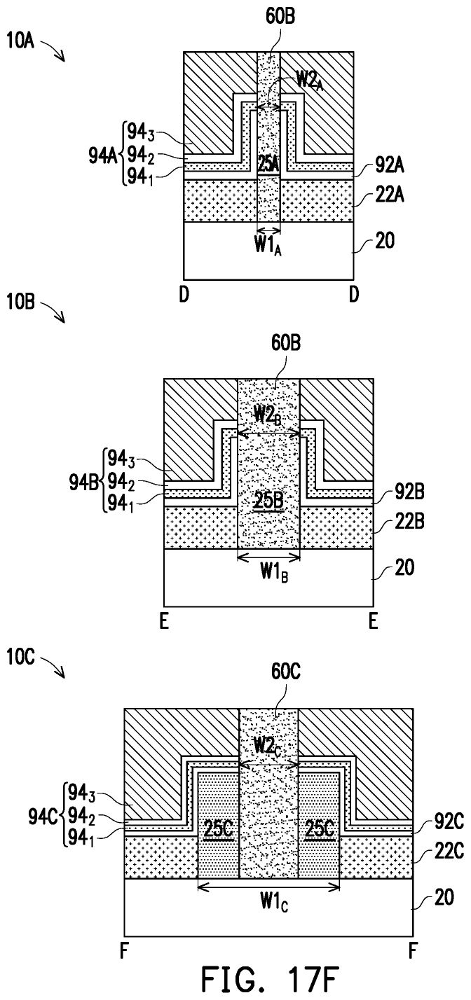

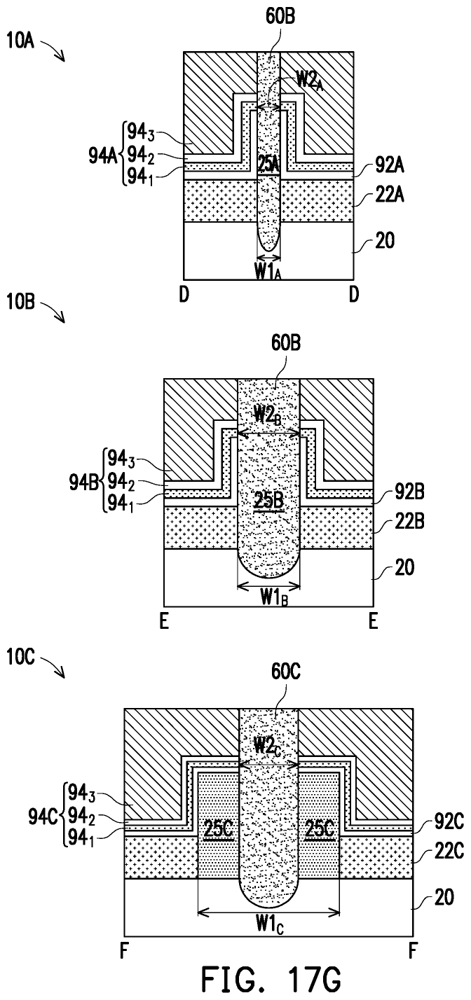

FIG. 12G illustrates an embodiment in which the gate isolation opening 56 may extend fully through the STI regions 22 and a portion of the substrate 20. FIG. 12G also shows an embodiment in which no dielectric fin 25 is present when the width W3 of the dielectric fine is the same as the width W2 of the opening 56. In alternative embodiments, a portion of dielectric fin 25 remains when the width W3 of the dielectric fine 25 is smaller than the width W2 of the opening 56 similar to dielectric fin 25C shown in FIG. 17B.

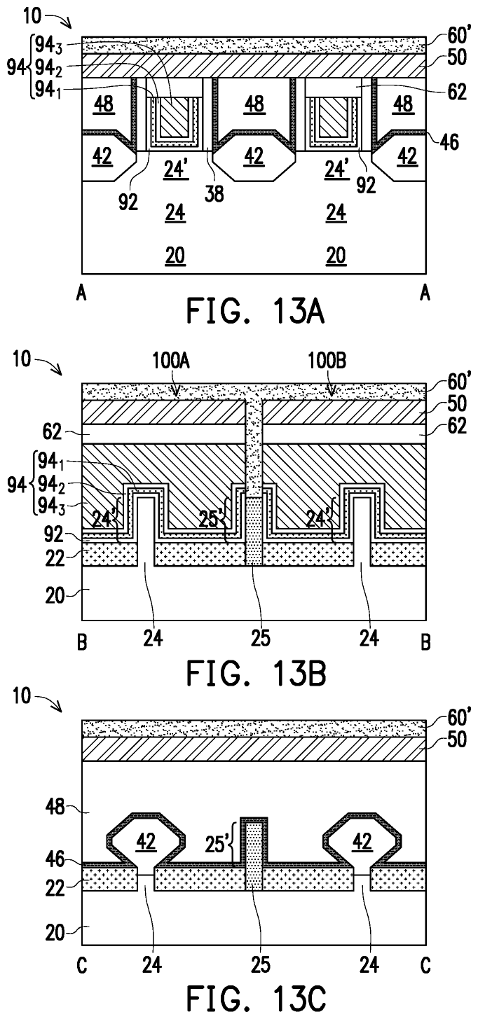

In FIGS. 13A, 13B, and 13C, a dielectric material 60′ is formed within the gate isolation openings 56 and over the structure, in accordance with some embodiments. The dielectric material 60′ may be an oxide, such as silicon oxide, a nitride, such as a silicon nitride or silicon oxynitride, the like, or a combination thereof. The dielectric material 60′ may be formed by a suitable process such as CVD, HDP-CVD, FCVD, the like, or a combination thereof. These or other dielectric materials may be formed by any acceptable process. The dielectric material 60′ may be a material the same as or different from the dielectric fin 25.

In FIGS. 14A, 14B, and 14C, a planarization process is performed to form gate isolation structures 60, in accordance with some embodiments. The planarization process removes excess dielectric material 60′ from the surface of the structure, with the remaining portions of the dielectric material 60′ within the gate isolation openings 56 forming the gate isolation structures 60. In some embodiments, the planarization process comprises an etching process, such as a wet etching process or a dry etching process, a CMP process, a mechanical grinding process, the like, or a combination thereof. Surfaces of the gate isolation structures 60, the hard masks 62, and the first ILD 48 may be exposed after the planarization process, and may be level with the hard masks 62 and the first ILD 48. The gate isolation structures 60 provide isolation between the gate stacks 100A and 100B. in some embodiments, the gate isolation structures 60 is referred to as a cut metal gate (CMG) isolation.

As shown in FIG. 14B, the remaining gate isolation structures 60 may have the approximate dimensions and profile as portions of the corresponding gate isolation openings 56. This is also the case for gate isolation openings 56 having different depths, such as those shown in FIGS. 12D to 12G. By controlling the etching of the gate isolation openings 56, the shape and size of the gate isolation structures 60 may be controlled. The gate isolation structures 60 may be formed having a top width that is about the same as or less than a bottom width. Thus, the gate isolation structures 60 may be formed having vertical sidewalls, or may be formed having angled sidewalls or a tapered width. The bottom width may be about the same as the lower width W2 of the corresponding gate isolation opening 56, in some cases. The bottom width of a gate isolation structure 60 may be smaller than, or about the same as a width W3 of a corresponding dielectric fin 25. These are examples, and other sizes, shapes, or dimensions are possible.

Turning to FIGS. 14D to 14G, gate isolation structures 60 are illustrated in accordance with alternative embodiments. The gate isolation structures 60 shown in FIGS. 14D to 14G are shown in a cross-sectional view similar to FIG. 14B. FIG. 14D illustrates an embodiment in which the gate isolation structure 60 extends into dielectric fin 25 such as may be formed from the gate isolation opening 56 of the embodiment shown in FIG. 12D. In FIG. 14D, a bottom surface of the gate isolation structure 60 is lower than a top surface of the fin 24, and higher than a top surface of the STI region 22.

FIG. 14E illustrates an embodiment in which the gate isolation structure 60 extends into the STI regions 22, such as may be formed from the gate isolation opening 56 of the embodiment shown in FIG. 12E. In FIG. 14E, a bottom surface of the gate isolation structure 60 is between a top surface and a bottom surface of the STI region 22.

FIG. 14F also shows an embodiment in which the gate isolation structure 60 extends into bottom surface of the STI region 22, such as may be formed from the gate isolation opening 56 of the embodiment shown in FIG. 12F. In some embodiments, the gate isolation structure 60 may extend fully through the STI regions 22.

FIG. 14G also shows an embodiment in which the gate isolation structure 60 extends into the substrate 20, such as may be formed from the gate isolation opening 56 of the embodiment shown in FIG. 12G. In some embodiments, the gate isolation structure 60 may extend fully through the STI regions 22 and a portion of the substrate 20.

Returning to FIGS. 15A, 15B, and 15C, a second ILD 108 is deposited over the first ILD 48. In some embodiments, the second ILD 108 is a flowable film formed by a flowable CVD method. In some embodiments, the second ILD 108 is formed of a dielectric material such as PSG, BSG, BPSG, USG, or the like, and may be deposited by any suitable method, such as CVD, PECVD and FCVD.

In FIGS. 16A, 16B, and 16C, gate contacts 110 and source/drain contacts 112 are formed through the second ILD 108 and the first ILD 48, in accordance with some embodiments. Openings for the source/drain contacts 112 are formed through the first and second ILDs 48 and 108, and openings for the gate contact 110 are formed through the second ILD 108 and the hard mask 62. The openings may be formed using acceptable photolithography and etching techniques. A liner, such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 108. The remaining liner and conductive material form the source/drain contacts 112 and gate contacts 110 in the openings. An anneal process may be performed to form a silicide at the interface between the epitaxial source/drain regions 42 and the source/drain contacts 112. The source/drain contacts 112 are physically and electrically coupled to the epitaxial source/drain regions 42, and the gate contacts 110 are physically and electrically coupled to the gate electrodes 94. The source/drain contacts 112 and gate contacts 110 may be formed in different processes, or may be formed in the same process. Although shown as being formed in the same cross-sections, it should be appreciated that each of the source/drain contacts 112 and gate contacts 110 may be formed in different cross-sections, which may avoid shorting of the contacts.

Although not explicitly shown, a person having ordinary skill in the art will readily understand that further processing steps may be performed on the structure in FIGS. 16A, 16B, and 16C. For example, various Inter-Metal Dielectrics (IMD) and their corresponding metallizations may be formed over the second ILD 108.

FIGS. 17A, 17B, 17C, 17D, 17E, 17F and 17G illustrate top views and cross-sectional views of intermediate stages in the formation of an integrated circuit having gate isolation structures, in accordance with some embodiments.

FIG. 17A illustrates a top view of an integrated circuit, in accordance with some embodiments of the present disclosure. FIGS. 17B, 17C, 17D, 17E, 17F and 17G are illustrated along cross-sections D-D, E-E and FF of FIG. 17A, in accordance with various embodiments of the present disclosure.

In FIG. 17A to FIG. 17C, an integrated circuit includes devices 10A, 10B and 10C formed in regions R1, R2 and R3 of a substrate 20 respectively. The device 10A includes fins 24A, a dielectric fin 25A and gate electrodes 94A. The device 10B includes fins 24B, a dielectric fin 25B and gate electrodes 94B. The device 10C includes fins 24C, a dielectric fin 25C and gate electrodes 94C.

The fins 24A, 24B and 24C may extend along a same direction or different directions. In some embodiments, the fins 24A, 24B and 24C may extend along a direction D1 as shown in FIG. 17A. The fins 24A, 24B and 24C may have a same width or different widths. The fins 24A, 24B and 24C may have different pitches. In some embodiments, a pitch of the fins 24C is larger than a pitch of the fins 24B, and the pitch of the fins 24B is larger than a pitch of the fins 24A.

In FIG. 17A, the dielectric fin 25A is formed between the fins 24A, the dielectric fin 25B is formed between the fins 24B, and the dielectric fin 25C is formed between the fins 24C. In some embodiments, a width W1_{A} of the dielectric fin 25A is equal to a width WA of the fins 24A. A width W1_{B} of the dielectric fin 25B is larger than a width WB of the fins 24B. The width W1_{C} of the dielectric fin 25C is larger than a width We of the fins 24C. The width W1_{C} of the dielectric fin 25C is larger than the width W1_{B} of the dielectric fin 25B, and the width W1_{B} of the dielectric fin 25B is larger than the width W1_{A} of the dielectric fin 25A.

In FIG. 17A, the gate electrodes 94 (e.g., 94A, 94B and 94C) each extends along a direction D2 perpendicular to the direction D2, and thus may be referred to as metal gate lines. The gate electrode 94 (e.g., 94A, 94B or 94C) spans the fins 24 (e.g., 24A, 24B or 24C) and the dielectric fin 25 (e.g., 25A, 25B or 25C). In some embodiments, the gate electrode 94 (e.g., 94A, 94B or 94C) includes a liner layer 94₁, a work function tuning layers 94₂ and a fill material 94₃ as shown in FIG. 17B and FIG. 17C.

In some embodiments, the devices 10A, 10B and 10C each further include gate dielectric layer 92 (e.g., 92A, 92B or 92C). The gate dielectric layer 92 (92A, 92B or 92C) are located below the gate electrodes 94 (e.g., 94A, 94B or 94C) respectively. The gate dielectric layer 92 (e.g., 92A, 92B or 92C) is located between the gate electrode 94 (e.g., 94A, 94B or 94C) and the fin 24 (e.g., 24A, 24B or 24C), and between the gate electrode 94 (e.g., 94A, 94B or 94C) and the dielectric fin 25 (e.g., 25A, 25B or 25C).

The gate dielectric layer 92 (e.g., 92A, 92B or 92C) further cover and contact top surfaces of the STI region 22 (e.g., 22A, 22B or 22C) and sidewalls of the dielectric fin 25 (e.g., 25A, 25B or 25C). The gate dielectric layer 92 (e.g., 92A, 92B or 92C) protrude from a top surface of the dielectric fin 25 (e.g., 25A, 25B or 25C). Topmost surface of the gate dielectric layer 92 (e.g., 25A, 25B or 25C) is higher than top surface of the dielectric fin 25 (e.g., 25A, 25B or 25C).

The gate dielectric layers 92C further cover and contact portions of top surface of the dielectric fin 25C. The gate dielectric layer 92C located on the dielectric fin 25C is sandwiched longitudinally between the gate electrode 94C and the dielectric fin 25C. A topmost surface of the gate dielectric layer 92C located over the dielectric fin 25C is lower than a topmost surface of the gate electrode 94C located over the dielectric fin 25C.

In FIG. 17A to 17C, the device 10 (e.g., 10A, 10B or 10C) further include gate isolation structure 60 (e.g., 60A, 60B or 60C). In FIG. 17B, in some embodiments, the device 10 (e.g., 10A, 10B or 10C) further include a hard mask 62 (e.g., 62A, 62B or 62C) on the gate electrode 94 (e.g., 94A, 94B or 94C). The gate isolation structure 60 (e.g., 60A, 60B or 60C) extends through the hard mask 62 (e.g., 62A, 62B or 62C), the gate electrode 94 (e.g., 94A, 94B or 94C) and the gate dielectric layer 92 (e.g., 92A, 92B or 92C).

In FIGS. 17B and 17C, the topmost surface of the gate dielectric layer 92 (e.g., 92A, 92B or 92C) are higher than the top surface of the dielectric fin 25 (e.g., 25A, 25B or 25C), and lower than the top surface of the gate isolation structure 60 (e.g., 60A, 60B or 60C). Lower sidewalls of the gate isolation structure 60 (e.g., 60A, 60B or 60C) are in contact with the gate dielectric layer 92 (e.g., 92A, 92B or 92C), middle sidewalls of the gate isolation structure 60 (e.g., 60A, 60B or 60C) are in contact with the gate electrode 94 (e.g., 94A, 94B or 94C), and upper sidewalls of the gate isolation structure 60 (e.g., 60A, 60B or 60C) are in contact with the hard mask 62 (e.g., 62A, 62B or 62C). In some embodiments, top surface of the gate isolation structure 60 (e.g., 60A, 60B or 60C) are flush with top surfaces of the hard mask 62 (e.g., 62A, 62B or 62C). A contact area between the gate electrode 94 (e.g., 94A, 94B or 94C) and a sidewall of a first side of the gate isolation structure 60 (e.g., 60A, 60B or 60C) is greater than a contact area between the gate dielectric layer 92 (e.g., 92A, 92B or 92C) and the sidewall of the first side of the isolation structure 60 (e.g., 60A, 60B or 60C).

In FIG. 17C, in alternative embodiments, the device 10 (e.g., 10A, 10B or 10C) do not include any hard mask on the gate electrode 94 (e.g., 94A, 94B or 94C). The gate isolation structure 60 (e.g., 60A, 60B or 60C) extends through the gate electrode 94 (e.g., 94A, 94B or 94C) and the gate dielectric layer 92 (e.g., 92A, 92B or 92C). In some embodiments, lower sidewalls of the gate isolation structure 60 (e.g., 60A, 60B or 60C) are in contact with the gate dielectric layer 92 (e.g., 92A, 92B or 92C), and upper sidewalls of the gate isolation structure 60A are in contact with the gate electrode 94 (e.g., 94A, 94B or 94C). In some embodiments, a top surface of the gate isolation structure 60 (e.g., 60A, 60B or 60C) are flush with a top surface of the gate electrode 94 (e.g., 94A, 94B or 94C). A contact area between the gate electrode 94 (e.g., 94A, 94B or 94C) and a sidewall of a first side of the gate isolation structure 60 (e.g., 60A, 60B or 60C) is greater than a contact area between the gate dielectric layer 92 (e.g., 92A, 92B or 92C) and the sidewall of the first side of the isolation structure 60 (e.g., 60A, 60B or 60C).

In FIG. 17A to FIG. 17C, in the direction D2, a width W2A of the gate isolation structure 60A is equal to or smaller than a width W1_{A} of the dielectric fin 25A, a width W2_{B} of the gate isolation structure 60B is equal to or smaller than a width W1_{B} of the dielectric fin 25B, and a width W2c of the gate isolation structure 60C is equal to or smaller than a width W1_{C} of the dielectric fin 25C. In some embodiments, the width W2c of the gate isolation structure 60C is equal to or larger than the width W2_{B} of the gate isolation structure 60B. The width W2c of the gate isolation structure 60C and the width W2_{B} of the gate isolation structure 60B are equal and both larger than the width W2A of the gate isolation structure 60A. In some embodiments, the width W2A of the gate isolation structure 60A is equal to the width W1_{A} of the dielectric fin 25A, the width W2_{B} of the gate isolation structure 60B is equal to the width W1_{B} of the dielectric fin 25B, and the width W2c of the gate isolation structure 60C is smaller than the width W1_{C} of the dielectric fin 25C when the width W1_{A} of the dielectric fin 25A and the width W1_{B} of the dielectric fin 25B are smaller than 50 nm, and the width W1_{C} of the dielectric fin 25C is larger than 50 nm.

The gate isolation structure 60 (e.g., 60A, 60B or 60C) may extend deeper. In some embodiments, the gate isolation structure 60 (e.g., 60A, 60B or 60C) may extend into a portion of the dielectric fin 25A as shown in FIGS. 17D and 17E. In alternative embodiments, the gate isolation structure 60 (e.g., 60A, 60B or 60C) may extend to a bottom of the isolation region 22 (e.g., 22A, 22B or 22C) as shown in FIG. 17F. In alternative embodiments, the gate isolation structure 60 (e.g., 60A, 60B or 60C) may extend into a portion of the substrate 20 as shown in FIG. 17G. In FIG. 17B to 17G, at least a portion of the dielectric fin 25C remain to surround and contact the gate isolation structure 60C.

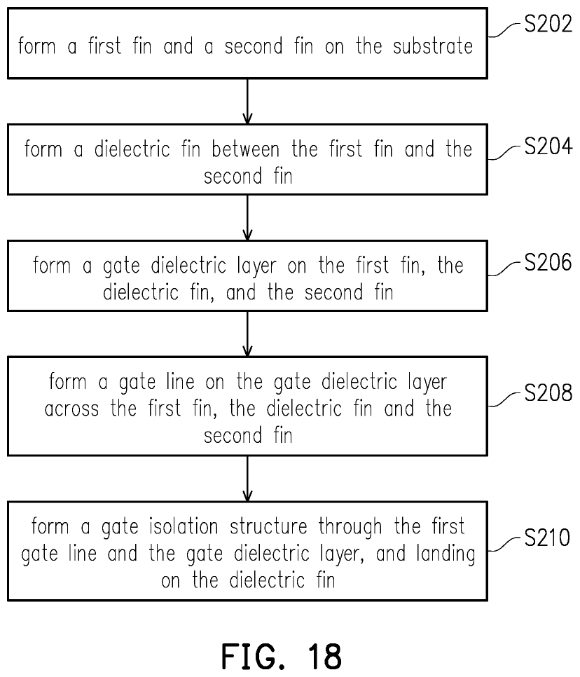

FIG. 18 illustrates a method of forming a FinFET device in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S202, a first fin and a second fin are formed on a substrate. FIG. 1 illustrates a perspective view corresponding to some embodiments of act S202.

At act S204, a dielectric fin is formed between the first fin and the second fin. The trench comprises a first part, a second part and a third part, and the third part is between and narrower than the first part and the second part. FIG. 2 illustrates a perspective view corresponding to some embodiments of act S204.

At act S206, a gate dielectric layer is formed on the first fin, the dielectric fin, and the second fin. FIG. 9A to FIG. 9C illustrate cross-sectional views corresponding to some embodiments of act S206.

At act S208, a metal gate line is formed on the gate dielectric layer across the first fin, the dielectric fin and the second fin. The gate dielectric layer is located between the metal gate line and the dielectric fin, between the metal gate line and the first fin, and between the metal gate line and the second fin. FIG. 9A to FIG. 9C illustrate cross-sectional views corresponding to some embodiments of act S208.

At act S210, gate isolation structure is formed through the first metal gate line and the gate dielectric layer, and landing on the dielectric fin. A top surface of the gate dielectric layer is lower than a top surface of the gate isolation structure. FIG. 10A to FIG. 14G illustrate cross-sectional views corresponding to some embodiments of act S210.

According to various embodiments, a semiconductor device and method of forming the same is provided in accordance with various embodiments. In particular, FinFET devices are formed in a gate-last process, where dummy gates formed of polysilicon are replaced by metal gates in intermediate steps of manufacturing. Openings are formed in the metal gates between neighboring fins using a patterning process. The patterning process is controlled such that a width of the opening is the same as or less than a width of a dielectric fin. An isolation material is deposited into the openings to form gate isolation structures on dielectric fins. By controlling a width of the openings to be smaller than a width of the dielectric fin, the loading effect, the process window and yield can be improved.

In accordance with some embodiments of the present disclosure, a FinFET device includes a first fin and a second fin on a substrate, a dielectric fin, a metal gate line, a gate dielectric layer, a gate isolation structure. The dielectric fin is located between the first fin and the second fin. The metal gate line is across the first fin, the dielectric fin and the second fin. The gate dielectric layer is located between the metal gate line and the dielectric fin, between the metal gate line and the first fin, and between the metal gate line and the second fin. The gate isolation structure extends through the first metal gate line and the gate dielectric layer, and landing on the dielectric fin. A top surface of the gate dielectric layer is lower than a top surface of the gate isolation structure.

In accordance with alternative embodiments of the present disclosure, a FinFET device includes a first fin and a second fin on a substrate, a dielectric fin, a metal gate line, a gate dielectric layer, and a gate isolation structure. The dielectric fin is located between the first fin and the second fin. The metal gate line is across the first fin, the dielectric fin and the second fin. The gate dielectric layer is located between the metal gate line and the dielectric fin, between the metal gate line and the first fin, and between the metal gate line and the second fin. The gate isolation structure extends through the first metal gate line and the gate dielectric layer, and landing on the dielectric fin. The metal gate line is in contact with upper sidewalls of the isolation structure.

In accordance with yet alternative embodiments of the present disclosure, a method of forming a FinFET device includes the following steps. A first fin and a second fin are formed on a substrate. A dielectric fin is formed between the first fin and the second fin. A gate dielectric layer is formed on the first fin, the dielectric fin, and the second fin. A metal gate line is formed on the gate dielectric layer across the first fin, the dielectric fin and the second fin. The gate dielectric layer is located between the metal gate line and the dielectric fin, between the metal gate line and the first fin, and between the metal gate line and the second fin. A gate isolation structure is formed through the first metal gate line and the gate dielectric layer, and landing on the dielectric fin. A top surface of the gate dielectric layer is lower than a top surface of the gate isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A FinFET device, comprising:
a substrate;
a first fin and a second fin on the substrate;
a dielectric fin between the first fin and the second fin;
a metal gate line across the first fin, the dielectric fin and the second fin;
a gate dielectric layer located between the metal gate line and the dielectric fin, between the metal gate line and the first fin, and between the metal gate line and the second fin; and
a gate isolation structure through the first metal gate line and the gate dielectric layer, and landing on the dielectric fin,
wherein a top surface of the gate dielectric layer is lower than a top surface of the gate isolation structure.

2. The FinFET device of claim 1, wherein a width of the gate isolation structure is equal to or smaller than a width of the dielectric fin.

3. The FinFET device of claim 2, wherein a width of the dielectric fin is equal to or greater than a width of the first fin and a width of the second fin.

4. The FinFET device of claim 1, wherein the top surface of the dielectric fin is covered by the gate dielectric layer.

5. The FinFET device of claim 1, wherein the gate dielectric layer located on the dielectric fin is sandwiched longitudinally between the metal gate line and the dielectric fin.

6. The FinFET device of claim 1, wherein a topmost surface of the gate dielectric layer located over the dielectric fin is lower than a topmost surface of the metal gate line located over the dielectric fin.

7. The FinFET device of claim 1, wherein the gate dielectric layer is in contact with lower sidewalls of the gate isolation structure.

8. A FinFET device, comprising:
a substrate;
a first fin and a second fin on the substrate;
a dielectric fin between the first fin and the second fin;
a metal gate line across the first fin, the dielectric fin and the second fin;
a gate dielectric layer located between the metal gate line and the dielectric fin, between the metal gate line and the first fin, and between the metal gate line and the second fin; and
a gate isolation structure through the first metal gate line and the gate dielectric layer, and landing on the dielectric fin,
wherein the metal gate line is in contact with upper sidewalls of the isolation structure.

9. The FinFET device of claim 8, wherein the gate dielectric layer is in contact with lower sidewalls of the isolation structure.

10. The FinFET device of claim 9, wherein a contact area between the metal gate line and a sidewall of a first side of the gate isolation structure is greater than a contact area between the gate dielectric layer and the sidewall of the first side of the isolation structure.

11. The FinFET device of claim 8, wherein a width of the dielectric fin is greater than a width of the first fin, a width of the second fin, and a width of the gate isolation structure.

12. The FinFET device of claim 8, wherein a width of the dielectric fin is greater than a width of the first fin, a width of the second fin, and equal to a width of the gate isolation structure.

13. The FinFET device of claim 8, wherein a width of the dielectric fin is equal to a width of the first fin, a width of the second fin, and a width of the gate isolation structure.

14. A method of forming a FinFET device, comprising:
forming a first fin and a second fin on a substrate;
forming a dielectric fin between the first fin and the second fin;
forming a gate dielectric layer on the first fin, the dielectric fin, and the second fin;
forming a metal gate line on the gate dielectric layer across the first fin, the dielectric fin and the second fin, wherein the gate dielectric layer is located between the metal gate line and the dielectric fin, between the metal gate line and the first fin, and between the metal gate line and the second fin; and
forming a gate isolation structure through the first metal gate line and the gate dielectric layer, and landing on the dielectric fin,
wherein a top surface of the gate dielectric layer is lower than a top surface of the gate isolation structure.

15. The method of claim 14, wherein the forming the gate isolation structure comprises:
performing a cutting process by patterning the first metal gate line and the gate dielectric layer to form an opening revealing the dielectric fin;
forming an insulating material over the metal gate line and filing in the opening; and
removing the insulating material from the metal gate line.

16. The method of claim 15, wherein the opening is formed to have a width equal to or less than a width of the dielectric fin.

17. The method of claim 15, wherein the dielectric fin is formed to have a width equal to or greater than a width of the first fine and a width of the second fin.

18. The method of claim 15, wherein the forming the gate isolation structure to contact the metal gate line and the gate dielectric layer.

19. The method of claim 15, wherein the gate isolation structure is formed to have a top surface higher than a top surface of the gate dielectric layer.

20. The method of claim 15, wherein the gate dielectric layer formed over the dielectric fin has a topmost surface lower than a topmost surface of the metal gate line formed over the dielectric fin.
